(19) United States
(12) Patent Application Publication
(10) Pub. No.: US 2010/0165681 A1
(43) Pub. Date: Jul. 1, 2010

(54) SEMICONDUCTOR DEVICE AND POWER CONVERTER USING THE SAME

(75) Inventors: Junichi Sakano, Hitachi (JP); Kenji Hara, Hitachinaka (JP); Shinji Shirakawa, Moriya (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(73) Assignee: Hitachi, Ltd.

(21) Appl. No.: 12/646,990

(22) Filed: Dec. 24, 2009

(30) Foreign Application Priority Data
Dec. 26, 2008 (JP) 2008-332412

(51) Int. Cl. H02M 7/06; H03K 17/687

(52) U.S. Cl. 363/123; 327/429

(57) ABSTRACT

In a driving circuit, for controlling the turning on and off of a main semiconductor switching device of an insulated gate type, in an insulated gate semiconductor switching device for electric power conversion, bipolar semiconductor devices of an insulated gate control type, particularly insulated gate bipolar transistors (IGBTs) are used at the output stage of a circuit that controls the gate voltage of the main semiconductor switching device.

### CLAIM OF PRIORITY

The present application claims priority from Japanese patent application serial No. 2008-332412, filed on Dec. 26, 2008, the content of which is hereby incorporated by reference into this application.

### FIELD OF THE INVENTION

The present invention relates to a semiconductor device for driving a power semiconductor device and to a power converter that uses the semiconductor device.

### BACKGROUND OF THE INVENTION

Power semiconductor switching devices of the isolated gate type, typified by power metal oxide semiconductor field effect transistors (MOSFETs) and isolated gate bipolar transistors (IGBTs), are turned on and off by a voltage applied between their gate and source or between their gate and emitter. A driving circuit for controlling the turning on and off of a power semiconductor switching device of this type is disclosed in Japanese Patent Laid-open No. 2006-353093, for example. In Japanese Patent Laid-open No. 2006-353093, MOSFETs are used to configure switches at an output stage in a driving circuit for driving six MOSFETs, which are main switches for controlling a motor current. One of the MOSFETs, which are main switches for controlling electric power, is Q1. Voltage VGS between the gate and source of Q1 is controlled by p-type MOSFETs M1 and M5, and n-type MOSFETs M2, M3, and M4, which are connected to the gate of Q1 via a resistor through terminals T2 and T3. When the p-type MOSFETs are turned on and the n-type MOSFETs are turned off, Q1 is turned on, enabling a main current to flow. When the p-type MOSFETs are turned off and the n-type MOSFETs are turned on, Q1 is turned off, shutting down the main current. The speed at which the main switching device is turned on and off depends on the speed at which the VGS changes in response to the charging and discharging of a capacitor disposed between the gate and emitter of the main switching device, which is caused by the current flow or shut down by the p-type and n-type MOSFETs. The sizes of the p-type and n-type MOSFETs are determined so that a current that is enough to change the VGS in the switching time of a necessary main switch can flow.

### SUMMARY OF THE INVENTION

In an arrangement as descried above, as the current capacity of the main switching device increases, its gate capacity also increases and thereby the current of the MOSFET, which is a device at the output stage of the driving circuit, also increases, resulting in the need to increase the device area. The driving circuit thus becomes difficult to integrate and the output stage of the driving circuit needs to be configured with individual devices, which not only increases the number of parts but also increases the area of the driving circuit. Accordingly, a power converter including the driving circuit and main switch is also enlarged.

The present invention addresses the above problem with the object of providing a small driving circuit with high performance that is integrated by increasing the current driving capacity of devices at the output stage of the driving circuit and reducing their sizes and also providing a small power converter with high performance that uses the driving circuit.

A driving circuit in an aspect of the present invention, which controls the turning on and off of a main semiconductor switching device of an isolated gate type, uses insulated gate bipolar semiconductor devices at the output stage of a circuit that controls the gate voltage of the main semiconductor switching device.

In a preferred embodiment of the present invention, isolated gate bipolar transistors are used as the insulated gate bipolar semiconductor devices at the output stage.

In another preferred embodiment of the present invention, a plurality of channels is formed for a single collector of the isolated gate bipolar transistor.

In still another preferred embodiment of the present invention, the isolated gate bipolar transistors at the output stage and a control circuit for controlling the output stage are integrated on a dielectric isolated semiconductor.

In a specific preferred embodiment of the present invention, the isolated gate bipolar transistor of the semiconductor device has a second conductive layer in a second conductive buffer layer, which is formed so that it encloses a first conductive collector layer, the second conductive layer and the first conductive collector layer being interconnected by a collector metal electrode.

In another specific preferred embodiment of the present invention, a power converter is configured with gate driving circuits, each of which is formed by the semiconductor device described above, and a main switching device for controlling electric power, a gate of the main switching device being controlled by the gate driving circuits.

According to the preferred embodiments of the present invention, a small driving circuit with high performance can be provided, that is integrated by increasing the current driving capacity of devices at the output stage of the driving circuit and reducing their sizes.

A small power converter with high performance can also be provided by using driving circuits of this type.

Other purposes and objects of the present invention will be clarified in the embodiments described below.

### BRIEF DESCRIPTION OF THE DRAWINGS

FIG. 1 shows the circuit in a semiconductor device in a first embodiment of the present invention.

FIG. 2 is a cross sectional view illustrating the structure of the semiconductor of the semiconductor device in the first embodiment of the present invention.

FIG. 3 is a cross sectional view illustrating the structure of the semiconductor of a semiconductor device in a second embodiment of the present invention.

FIG. 4 illustrates voltage-current characteristics of an IGBT and a MOSFET applicable to the present invention.

FIG. 5 is a cross sectional view showing the structure of a semiconductor in a semiconductor device in a third embodiment of the present invention.

FIG. 6 shows the circuit in a semiconductor device in a fourth embodiment of the present invention.

FIG. 7 shows the circuit of a power converter that uses the semiconductor device that embodies the present invention.

### DESCRIPTION OF THE PREFERRED EMBODIMENTS

Embodiments of the present invention will be described in detail with reference to the attached drawings.

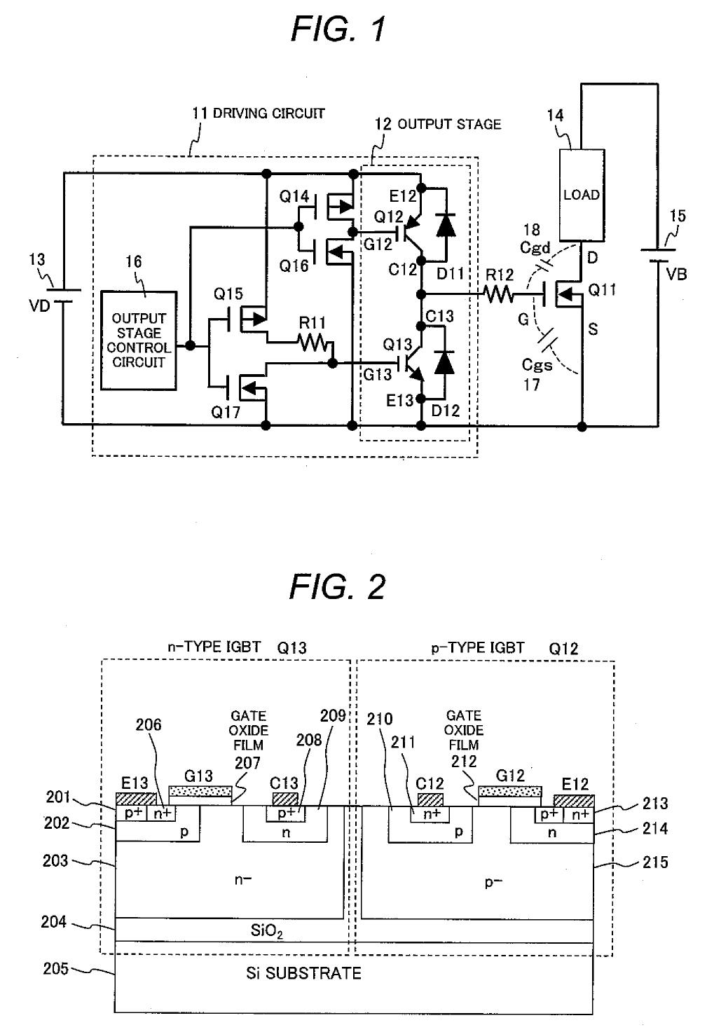

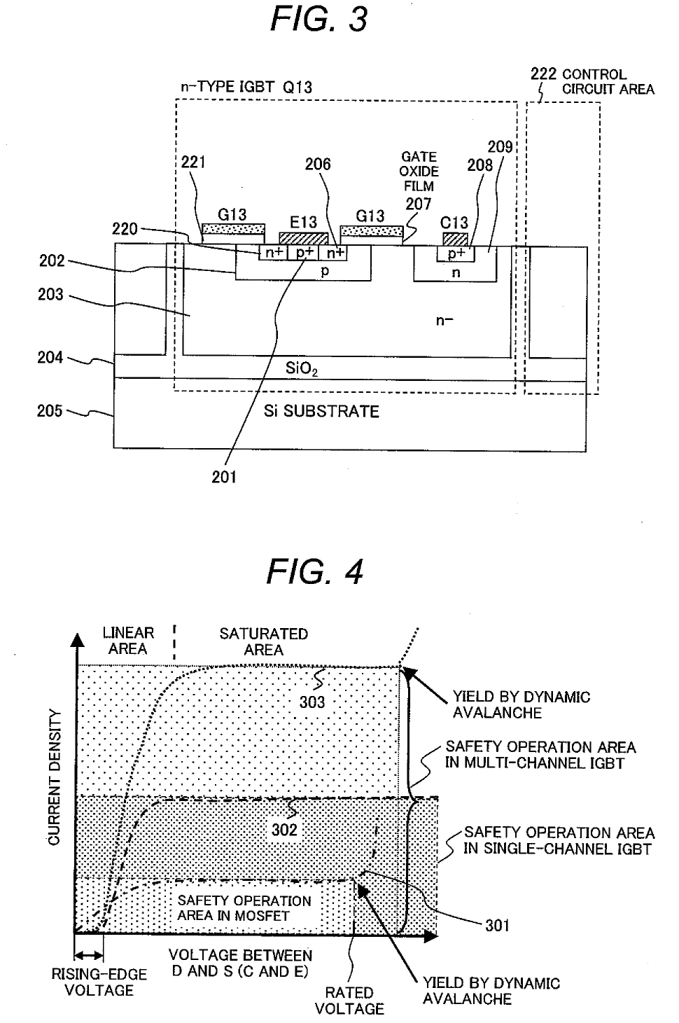

FIG. 1 shows the circuit in a semiconductor device and a power converter using the same in a first embodiment of the present invention. FIG. 2 is a cross sectional view illustrating the structure of the semiconductor of the semiconductor device in the first embodiment of the present invention. FIG. 3 is a cross sectional view illustrating the structure of the semiconductor of a semiconductor device in a second embodiment of the present invention. These semiconductor devices are examples in which devices are integrated on a Si substrate, which is isolated from the devices through a silicon dioxide (SiO₂) film.

In FIG. 1, a power MOSFET Q11, connected to a power supply VB 15 through a load 14, is a main switching device, which is controlled by a driving circuit 11 through a gate resistor R12 and coverts electric power. The output stage 12 of the driving circuit 11 is configured with a p-type isolated gate bipolar transistor (IGBT) Q12 and an n-type IGBT Q13, to which diodes D11 and D12 are respectively connected back-to-back. The gate G12 of the IGBT Q12 is driven by MOSFETs Q14 and Q16, and the gate G13 of the IGBT Q13 is driven by MOSFET Q15 and Q17. The IGBTs Q12 and Q13 flow currents from a gate power supply VD 13 to a capacitor Cgs 17 disposed between the gate and source of the main switching device Q11 to charge the capacitor Cgs 17 or discharge it, according to a command from an output stage control circuit 16. A resistor R11 is connected between the gate G13 of the IGBT Q13 and the MOSFET Q15.

The IGBTs Q12 and Q13 at the output stage are integrated on a Si substrate, which is isolated from these devices by a dielectric SiO₂ film, as shown in FIG. 2. The withstand voltage between the collector and emitter of IGBTs Q12 and Q13 is set to about 40 to 60V, which is twice as less as the power supply voltage (20 to 30V, for example) of the gate power supply VD, to allow a margin. The voltage of the main circuit power supply VB is assumed to be about 10V to several kilovolts.

In FIG. 2, reference numeral 201 indicates a back gate power supply p+ layer, 202 indicates a p-type channel layer, 203 indicates an n-type active Si layer, 215 indicates a p-type active Si layer, 204 indicates a buried oxide film for device isolation, and 205 indicates a Si support substrate, which is a dielectric isolation substrate. Reference numeral 206 indicates an emitter n+ layer, 207 and 212 indicate gate oxide films, 208 indicates a collector p+ layer, 209 indicates an n-type buffer layer, 210 indicates a p-type buffer layer, 211 indicates a collector n+ layer, 213 indicates a back gate power supply n+ layer, and 214 indicates an n-type channel layer.

In FIG. 3, elements identical to those in FIG. 2 are denoted by the same reference numerals, and reference numeral 220 indicates an emitter n+ layer, 221 indicates a gate oxide film, and 222 indicates an area where a control circuit is integrated.

FIG. 4 illustrates voltage-current characteristics when the gate in the semiconductor devices, shown in FIGS. 2 and 3, that embody the present invention is turned on. In the drawing, reference numeral 301 indicates a MOSFET characteristic curve, 302 indicates a single-channel IGBT characteristic curve, and 303 indicates a multi-channel IGBT characteristic curve.

In the semiconductor device in which the horizontal n-type IGBT and horizontal p-type IGBT at the output stage are integrated, each IGBT includes a pn diode, which is formed by adding, for example, the p+ layer 208 in FIG. 2 to the drain of a MOSFET and thereby includes the p+ layer 208 and n layer 209, as shown in FIGS. 2 and 3. Therefore, a rising-edge voltage at about 1V is generated as shown in the voltage-current characteristics in FIG. 4. Accordingly, IGBTs of this type are widely used in applications in which power supply voltages exceed several hundred voltages at which a conductivity modulation effect by a bipolar operation becomes significant. In applications in which a low-voltage area is used, MOSFETs that do not generate a rising-edge voltage and have a low resistance are widely used.

As the result of consideration by the inventors, it was found that although an IGBT causes a rising-edge voltage, it is an effective component of an output stage in an integrated circuit that controls the gate of an insulated gate power semiconductor used as a capacitive load even when the withstand voltage of the IGBT is in the range from about 5V to 40V, as detailed below.

In an IGBT, in addition to a gate-controlled majority carrier current, a current is added that is generated when minority carriers are injected due to a bipolar operation. Accordingly, as clarified by comparison between the characteristic curves 301 and 302 in FIG. 4, it is possible to drive a current that is at least two times higher in the saturated area when compared with a MOSFET in which only a gate-limited majority carrier current flows. The IGBT differs in the structure from a MOSFET only in that the p+ layer 208 in FIG. 2, for example, is replaced with an n+ layer, so an increase in size, which is brought by the use of the IGBT, is small.

The gate capacitors Cgs 17 and Cgd 18 of the main switching device are charged and discharged mainly by the current in the saturated area. When characteristics by which a highly saturated current is obtained are used, the devices at the output stage can be downsized. A high resistance is indicated in a low-voltage area due to the presence of the rising-edge voltage, as described above. If the rising-edge voltage is larger than a gate threshold voltage at which a current starts to flow in the main switching device, there is the risk of a malfunction due to noise or the like. However, this is not problematic because the rising-edge voltage is about 1V. By comparison, the threshold voltages of most main switching devices are 3V or higher. A loss E for driving the capacitive load is given by E=C×Vd̂2×f, where C is a capacity, Vd is a power supply voltage, and f is a frequency, indicating that E does not depend directly on the rising-edge voltage of each device at the output stage. Accordingly, the loss of the driving circuit does not increase.

The IGBT switches slower than the MOSFET because minority carriers are stored in the IGBT, but the IGBT can operate at up to several tens of MHz in capacitive load driving when the device structure is optimized. This operating speed is adequate for the device at the output stage in the gate driving circuit in the main switch included in general converters operating at speeds up to about 100 kHz.

It was also found that the IGBT has a high-level injection effect brought by minority carriers, so a rise in electric field strength does not easily occur, the rise being a problem when the majority carrier current increases, so a dynamic avalanche yield occurs at a higher current than in the MOSFET. Accordingly, when, for example, the gate oxide films 207 and 212 are further thinned to improve the driving capacity or the channel layers 202 and 214 are bonded at a shallow depth to increase the gate driving capacity, a high-current driving capacity can be obtained.

The second embodiment shown in FIG. 3 is a multi-channel IGBT in which the gate G13 of the IGBT is provided at both sides of the emitter E13 so that two channels are formed for a single collector C₁₃ to increase the gate capacity. With the IGBT of this type, a saturated current two times higher than the characteristic curve 302 of the single-channel IGBT is obtained, as indicated by the characteristic curve 303 in FIG. 4. As the number of channels is increased, the driving capacity can be further optimized.

Even if an insulated gate thyristor, which is another insulated gate bipolar device, is used as the device at the output stage, the same effect as when the IGBT is used at the output stage can be obtained.

As described above, the present invention can improve the current driving capacity of the device at the output stage and can easily integrate the circuit at the output stage, in which individual devices have needed to be used.

When the current driving capacity of the device at the output stage, which is integrated according to the present invention, is significantly increased, an overlap may occur between a period during which the IGBT Q12 is turned on and another period during which the IGBT Q13 is turned on. In this case, since a high pass-through current flows from the control power supply VD, the integrated circuit may generate heat. To prevent this, it is desirable to provide a non-lapping period, during which both IGBTs are turned off, between the turned-on period of IGBT Q12 and the turned-on period of IGBT Q13. In the circuit in the embodiment shown in FIG. 1, the non-lapping period is provided by using the resistor R11, by which the rise of the gate voltage of IGBT Q13 is delayed to delay only the time at which IGBT Q13 is turned on. In the embodiment in FIG. 1, the diodes D11 and D12 are respectively connected back-to-back to the IGBTs Q12 and Q13, which are paired, to clamp the gate voltage. In the IGBTs Q12 and Q13, a current generally does not flow in the reverse direction. To prevent the gate in Q11 from undergoing dielectric breakdown, therefore, the diodes D11 and D12 are connected back-to-back so that when the gate voltage changes, through the capacitor Cgd 18 or the like, to the voltage of the power supply VD or higher or to below the source voltage, the gate voltage is clamped.

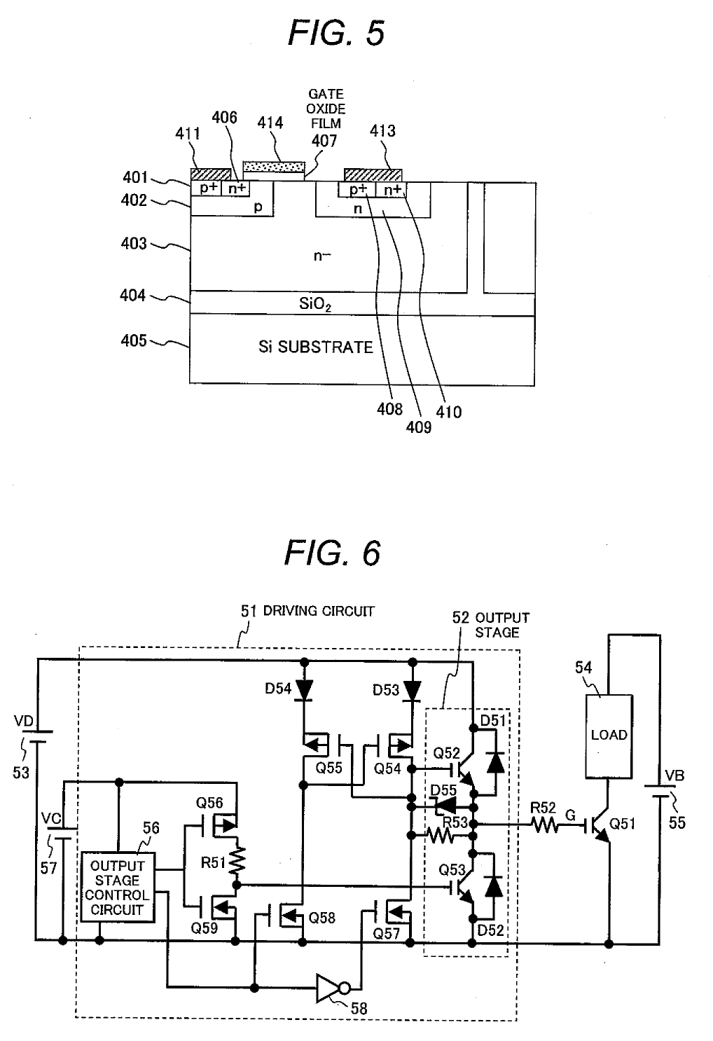

FIG. 5 is a cross sectional view showing the structure of a semiconductor in a semiconductor device in a third embodiment of the present invention. In this embodiment, only the structure of an n-type IGBT corresponding to the n-type IGBT in FIG. 2 is shown; a p-type IGBT corresponding to Q12 is omitted. In the drawing, reference numeral 401 indicates a back gate power supply p+ layer, 402 indicates a p-type channel layer, 403 indicates an n-type active Si layer, 404 indicates a buried oxide film for device isolation, and 405 indicates a Si support substrate, which is a dielectric isolation substrate. Reference numeral 406 indicates an emitter n+ layer, 407 indicates a gate oxide film, 408 indicates a collector p+ layer, 409 indicates an n-type buffer layer, 410 indicates an n+ layer for buffer layer power supply, 411 indicates an emitter electrode, 413 indicates a collector electrode, and 414 indicates a gate electrode.

In this embodiment, the n+ layer 410 formed in the n-type buffer 409 of the n-type IGBT, and the n+ layer 410 and collector p+ layer 408 are interconnected by the collector metal electrode 413. Since the IGBT and a MOSFET are connected in parallel in the same device, the action of the diode included in the MOSFET provides the same effect as when the diodes D11 and D12 are included in the IGBT in the embodiment shown in FIG. 1. In addition, since the rising-edge voltage is eliminated, it is possible to enable the driving of a main switching device with a low gate threshold. If the structure is completed as indicated in the cross sectional view in FIG. 5 in the direction perpendicular to the drawing sheet, the pn junction between the collector p+ layer 408 and n-type buffer layer 409 is not easily forward biased and thus IGBT operation is largely reduced, making it difficult to achieve driving capacity improvement, which is the original object of the present invention. Accordingly, n+ layers 410 need to be formed intermittently in the n-type buffer layer 409 in the direction perpendicular to the drawing sheet. In this case, although, in the drawing, the p+ layer 408 and n+ layer 410 are disposed in the horizontal direction on the drawing sheet, it is desirable to alternately dispose p+ layers 408 and n+ layers 410 in the direction perpendicular to the drawing sheet so as to reduce the width of the device in the horizontal direction.

In this embodiment, since the MOSFET is included in the IGBT, the high current driving capacity of the IGBT tends to decrease. As another embodiment to prevent this decrease, instead of including the MOSFET in the IGBT, a small MOSFET of the same conductive type may be provided in another Si active area that is isolated by a dielectric body. Then, the collector of the IGBT and the drain of the MOSFET are interconnected, the emitter of the IGBT and the source of the MOSFET are interconnected, and the gate of the IGBT and the gate of the MOSFET are interconnected. Since the rising-edge voltage is eliminated, it is possible to enable the driving of a main switching device with a low gate threshold.

FIG. 6 shows the circuit in a semiconductor device in a fourth embodiment of the present invention. This embodiment is achieved by replacing the p-type IGBT Q12 at the output stage in the embodiment in FIG. 1 with an n-type IGBT Q52. The gate withstand voltages of IGBTs Q52 and Q53 are lower than the voltage of the gate power supply VD. In this embodiment, the voltage of a gate power supply VC 57 of IGBT Q53 at the output stage is lower than the voltage of the gate power supply VD of the main switching device. Specifically, the voltage of the gate power supply VC is assumed to be about 5V; by comparison, the voltage of the gate power supply VD is about 15V. The degree of majority carrier movement in the n-type IGBT is higher than in the p-type IGBT, enabling the current driving capacity to be approximately doubled. To drive an n-type IGBT, a power supply generating a voltage higher than the voltage of the gate power supply VD is generally required to drive the gate. In this embodiment, however, an operation is possible without such an additional power supply. That is, when Q58 is turned on and Q54 is turned on, a rise of the gate voltage turns on the n-type IGBT Q52. The emitter voltage of IGBT Q52 then rises and reaches the voltage of the gate power supply VD. Even if the gate voltage of IGBT Q52 exceeds the voltage of the gate power supply VD, the voltage between the gate and emitter of IGBT Q52 is held because the diode D53 acts to block a reverse flow and prevents charges from being released from the gate of IGBT Q52 through the diode included in Q54 to the gate power supply VD. Accordingly, no additional power supply is required to drive IGBT Q52, achieving a driving circuit that is compact and can be easily integrated. Specifically, the circuit at the output stage includes a first n-type conductive isolated gate bipolar transistor Q52 for supplying a current to a gate G of the main semiconductor switching device Q51 to charge the gate and a second n-type conductive isolated gate bipolar transistor Q53 for extracting a current from the gate of the main semiconductor switching device Q51 to discharge the gate; the driving circuit further includes a circuit means D53 for preventing a current from being released from the gate of the first n-type conductive isolated gate bipolar transistor Q52 to the gate power supply VD for the main switching device when the electric potential of the gate of the first n-type conductive isolated gate bipolar transistor Q52 exceeds the voltage of the power supply VD for the main switching device.

In this embodiment, since low voltages are applied to the gates of Q52 and Q53, it is also possible that these devices have a high driving capacity and a reduced size by thinning the insulated film. A Zener diode D55 is provided to prevent an excessive voltage from being applied between the gate and emitter of Q52.

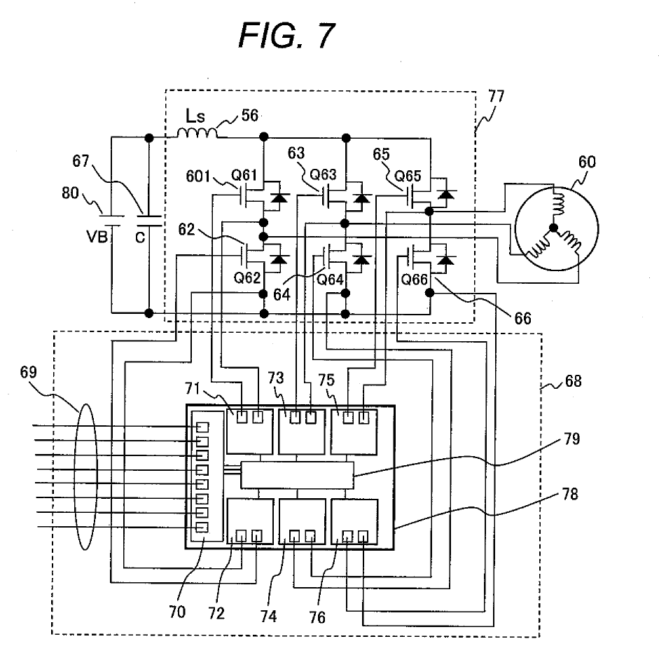

FIG. 7 shows the circuit of an exemplary power converter that uses the semiconductor device that embodies the present invention; the power inverter is a three-phase inverter for driving a motor. In the drawing, reference numeral 60 indicates a three-phase motor, which is used as a load, 61, 63, and 65 respectively indicate power MOSFETs Q61, Q63, and Q65 of U-, V-, and W-phase upper arms, and 62, 64, and 66 respectively indicate power MOSFETs Q62, Q64, and Q66 of U-, V-, and W-phase lower arms. Reference numeral 67 indicates a power supply capacitor C, 68 indicates a driving circuit substrate, 69 indicates control I/O signal lines, and 78 indicates a three-phase inverter driving integrated circuit formed on a single chip, the circuit being formed by using the driving circuit according to the present invention. The three-phase inverter driving integrated circuit 78 includes a control circuit part 70, driving circuit parts 71, 73, and 75 for the U-, V-, and W-phase upper arms, and driving circuit parts 72 74 and 76 for the U-, V-, and W-phase lower arms; these driving circuit parts are wired to the corresponding power MOSFETs that they drive. Reference numeral 77 indicates a power module, 79 indicates a bidirectional level converting circuit, and 80 indicates a power supply VB. The output stage of the driving circuit part in each phase can be made compact because it can have a high current driving capacity according to the present invention. Even when the capacities of the power MOSFETs to be driven by the driving circuit parts in the phases are large, the driving circuit parts can be easily integrated on a single chip. Furthermore, since the output stage is small, other peripheral circuits can also be easily integrated. Accordingly, the driving circuit substrate can be downsized, and it can also be mounted in a power module, making the power converter compact and improving its performance.

According to the embodiments of the present invention described above, the current driving capacity of each device at the output stage in a driving circuit can be increased and the size of the device can be reduced, so a small integrated driving circuit with high-performance can be provided. Furthermore, a small power converter with high performance can be provided by using driving circuits of this type.

What is claimed is:

1. A semiconductor device, wherein a driving circuit for controlling the turning on and off of a main semiconductor switching device of an insulated gate type uses an insulated gate bipolar semiconductor device at an output stage of a circuit that controls a gate voltage of the main semiconductor switching device.

2. The semiconductor device according to claim 1, wherein an isolated gate bipolar transistor is used as the insulated gate bipolar semiconductor device at the output stage.

3. The semiconductor device according to claim 2, wherein a plurality of channels are formed for a single collector of the isolated gate bipolar transistor.

4. The semiconductor device according to claim 2, wherein the isolated gate bipolar transistor at the output stage and a control circuit for controlling the isolated gate bipolar transistors are integrated on a dielectric isolated semiconductor.

5. The semiconductor device according to claim 2, wherein a second conductive layer is formed in a second conductive buffer layer, which is formed so as to enclose a first conductive collector layer, the second conductive layer and the first conductive collector layer being interconnected by a collector metal electrode.

6. The semiconductor device according to claim 2, wherein a MOS-type transistor is provided parallel to the isolated gate bipolar transistor, a drain of the MOS-type transistor being connected to a collector of the isolated gate bipolar transistor, a source of the MOS-type transistor being connected to an emitter of the isolated gate bipolar transistor.

7. The semiconductor device according to claim 2, wherein a pair of insulated gate bipolar transistors are provided at the output stage; a diode is connected back-to-back to each of the pair of insulated gate bipolar transistors.

8. The semiconductor device according to claim 2, wherein:
the circuit at the output stage includes a first n-type conductive isolated gate bipolar transistor for supplying a current to a gate of the main semiconductor switching device to charge the gate and a second n-type conductive isolated gate bipolar transistor for extracting a current from the gate of the main semiconductor switching device to discharge the gate; and
the driving circuit further includes a circuit means for preventing a current from being released from the gate of the first n-type conductive isolated gate bipolar transistor to a gate power supply for the main semiconductor switching device when an electric potential of the gate of the first n-type conductive isolated gate bipolar transistor exceeds a voltage of the power supply for the main semiconductor switching device.

9. The semiconductor device according to claim 2, wherein:
the circuit at the output stage includes, a first isolated gate bipolar transistor for supplying a current to a gate of the main semiconductor switching device to charge the gate and a second isolated gate bipolar transistor for extracting a current from the gate of the main semiconductor switching device to discharge the gate; and
the driving circuit includes a means for providing a non-lapping period to prevent an overlap from occurring between a period during which the first insulated gate bipolar transistor is turned on and another period during which the second insulated gate bipolar transistor is turned on when the driving circuit drives the first isolated gate bipolar transistor and the second isolated gate bipolar transistor.

10. The semiconductor device according to claim 1, wherein a withstand voltage of the insulated gate bipolar semiconductor device, which is of a control type, at the output stage of the circuit that controls the gate voltage of the main semiconductor switching device is not more than two times the voltage of a power supply for supplying a voltage to a gate of the main semiconductor switching device.

11. A power converter, comprising:
gate driving circuits, each of which is structured as described in claim 1; and
a main switching device for controlling electric power, a gate of the main switching device being controlled by the gate driving circuits.
